(19) United States
(12) Patent Application Publication
(10) Pub. No.: US 2025/0070792 A1
(43) Pub. Date: Feb. 27, 2025

(54) SUCCESSIVE APPROXIMATION REGISTER ANALOG-TO-DIGITAL CONVERTER AND OPERATION METHOD OF THE SAME

(71) Applicant: Realtek Semiconductor Corporation, Hsinchu (TW)

(72) Inventor: Wei-Cian HONG, Hsinchu (TW)

(21) Appl. No.: 18/637,417

(22) Filed: Apr. 16, 2024

(30) Foreign Application Priority Data
Aug. 24, 2023 (TW) 112131974

(51) Int. Cl. H03M 1/46

(52) U.S. Cl. CPC H03M 1/462

(57) ABSTRACT

A SAR ADC is configured to receive an input signal and comprises a DAC array and a SAR logic circuit coupled to each other. The DAC array comprises three DACs sampling an input voltage level of input signal and three comparators respectively connected in series with three DACs for generating a comparison result. The SAR logic circuit generates n^{th} bit of a conversion result according to comparison result in n^{th} comparison stage. In n^{th} comparison stage, SAR logic circuit chooses a first comparator to compare a sampling result of a first DAC with voltage level corresponding to the first (n-1) bits of conversion result, according to comparison result of (n-1)^{th} comparison stage, to generate comparison result, and adjusts sampling results of second and third DACs corresponding to second and third comparators to voltage levels respectively corresponding to cases where the n^{th} bit of conversion result is 0 and 1.

### RELATED APPLICATIONS

This application claims priority to Taiwan Application Serial Number 112131974, filed on Aug. 24, 2023, which is herein incorporated by reference in its entirety.

### BACKGROUND

### Technical Field

The present disclosure relates to a successive approximation register (SAR) analog-to-digital converter (ADC) and an operation method of the same. More particularly, the present disclosure relates to a SAR ADC sampling with three digital analog converters and an operation method of the same.

### Description of Related Art

Successive approximation register (SAR) analog-to-digital converter (ADC) is able to convert analog signals into digital signals with multiple bits through gradual approximation, and thus SAR ADC is widely used in various fields due to its high resolution characteristics.

However, after the comparator in the SAR ADC completes a comparison and determines one of the bits of the digital signal, the SAR ADC needs to wait for the digital-to-analog converter (DAC) in the SAR ADC switching the circuit structure to perform the next comparison and determine the next bit. In other words, the more number of bits of the digital signal that needs to be converted, the longer total time spent in switching the circuit structure of the DAC. Therefore, for high-resolution SAR ADCs, the switching time of the DAC lowers the conversion efficiency of the SAR ADCs. How to alleviate the effect of DAC switching on the conversion efficiency of SAR ADC has become one of the topics in this field.

### SUMMARY

A successive approximation register (SAR) analog-to-digital converter (ADC) is provided in present disclosure. The SAR ADC is configured to receive an input signal, and comprises a digital-to-analog converter (DAC) array and a SAR logic circuit. The DAC array is configured to receive the input signal and comprises three DACs and three comparators. The three DACs are configured to sample an input voltage level of the input signal. The three comparators are respectively connected in series with the three DACs, and are configured to respectively generate a comparison result. The SAR logic circuit is coupled to the DAC array, and is configured to generate the n^{th} bit of a conversion result according to the comparison result in an n^{th} comparison stage. In the nth comparison stage, the SAR logic circuit is configured to choose a first comparator of the three comparators to compare a sampling result of a first DAC of the three DACs with the voltage level corresponding to the first (n-1) bits of the conversion result, according to the comparison result of an (n-1)^{th} comparison stage, to generate the comparison result, and adjust sampling results of a second DAC and a third DAC of the three DACs corresponding to a second comparator and a third comparator of the three comparators to the voltage levels respectively corresponding to the cases where the n^{th} bit of the conversion result is 0 and 1. Wherein n is a positive integer greater than 1.

An operation method for operating a SAR ADC is provided in present disclosure. The SAR ADC is configured to receive an input signal and comprises a DAC array and a SAR logic circuit. The operation method comprises: (a) in an nth comparison stage, choosing a first comparator of three comparators of the DAC array by the SAR logic circuit, to compare a sampling result of a first DAC of three DACs of the DAC array with the voltage level corresponding to the first (n-1) bits of a conversion result, according to the comparison result of an (n-1)^{th} comparison stage, to generate a comparison result, and adjusting sampling results of a second DAC and a third DAC of the three DACs corresponding to a second comparator and a third comparator of the three comparators to the voltage levels respectively corresponding to the cases where the n^{th} bit of the conversion result is 0 and 1 by the SAR logic circuit; (b) comparing the input signal with the voltage level corresponding to the first (n-1) bits of the conversion result by the first comparator, to generate the comparison result; (c) generating the n^{th} bit of the conversion result according to the comparison result by the SAR logic circuit; and (d) repeating steps (a)-(c). The DAC array is coupled between the input signal and the SAR logic circuit, and the three comparators are respectively connected in series with the three DACs. The variable n is a positive integer greater than 1.

With the SAR ADC and the operation method of the same in present disclosure, the time that the SAR ADC waits for switching the internal DACs in different comparison stages can be reduced, thereby improving the efficiency of the SAR ADC in converting analog signals into digital signals while maintaining resolution.

It should be understood that both the foregoing general description and the following detailed description are by examples, and are intended to provide further explanation of the disclosure as claimed.

### BRIEF DESCRIPTION OF THE DRAWINGS

The present disclosure can be more fully understood by reading the following detailed description of the embodiment, with reference made to the accompanying drawings as follows.

FIG. 1 is a circuit diagram of a SAR ADC in accordance with some embodiments of the present disclosure.

FIG. 2A is a circuit diagram of a SAR ADC in time period P1 in accordance with some embodiments of the present disclosure.

FIG. 2B is a circuit diagram of a SAR ADC in time period P2 in accordance with some embodiments of the present disclosure.

FIG. 2C is a circuit diagram of a SAR ADC in time period P3 in accordance with some embodiments of the present disclosure.

FIG. 2D is a circuit diagram of a SAR ADC in time period P4 in accordance with some embodiments of the present disclosure.

FIG. 2E is a circuit diagram of a SAR ADC in time period P5 in accordance with some embodiments of the present disclosure.

FIG. 3 is a timing diagram of a sampling signal and channel selection signals in accordance with some embodiments of the present disclosure.

FIG. 4 is a flowchart of an operation method for operating a SAR ADC in accordance with some embodiments of the present disclosure.

### DETAILED DESCRIPTION

Reference will now be made in detail to the present embodiments of the disclosure, examples of which are illustrated in the accompanying drawings.

In the present disclosure, when an element is referred to as “connected”, it may mean “electrically connected” or “optical connected”. When an element is referred to as “coupled”, it may mean “electrically coupled” or “optical coupled”. “Connected” or “coupled” can also be used to indicate that two or more components operate or interact with each other. As used in the present disclosure, the singular forms “a”, “one” and “the” are also intended to include plural forms, unless the context clearly indicates otherwise. It will be further understood that when used in this specification, the terms “comprises (comprising)” and/or “includes (including)” designate the existence of stated features, steps, operations, elements and/or components, but the existence or addition of one or more other features, steps, operations, elements, components, and/or groups thereof are not excluded.

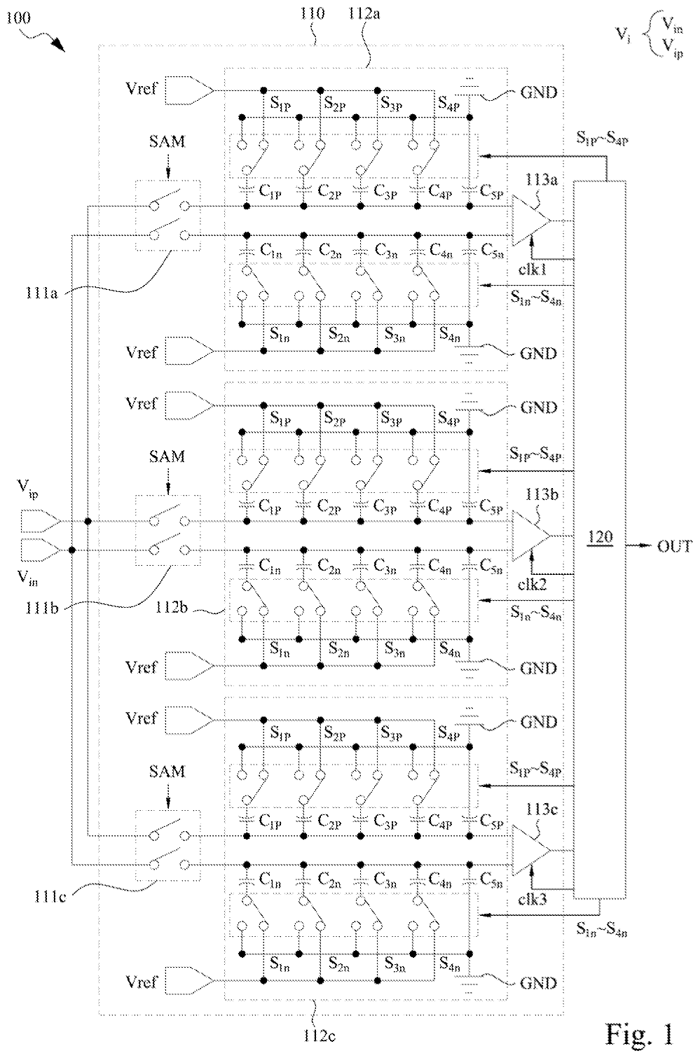

FIG. 1 is a circuit diagram of a successive approximation register (SAR) analog-to-digital converter (ADC) 100 in accordance with some embodiments of the present disclosure. In some embodiments, the SAR ADC 100 is configured to receive an input signal Vi and a reference voltage Vref, and comprises a digital-to-analog converter (DAC) array 110 and a SAR logic circuit 120. The SAR logic circuit 120 is configured to generate a conversion result OUT according to the voltage level of the input signal Vi.

In some embodiments, the conversion result OUT is an array comprising a plurality of bits. For example, the conversion result OUT may be a binary array comprising 4 bits.

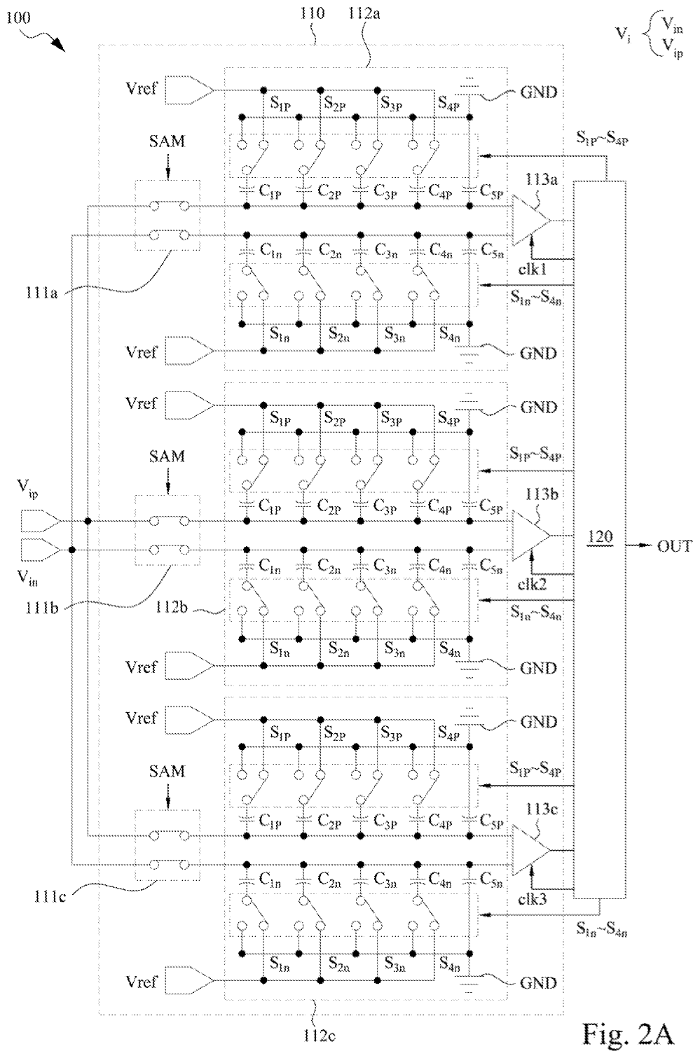

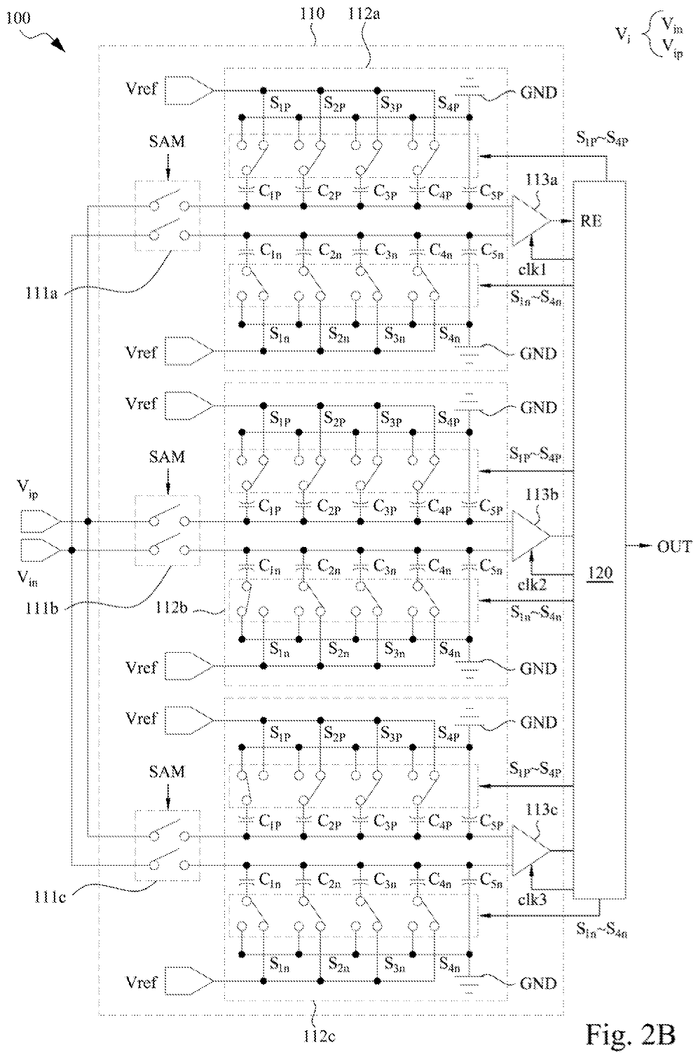

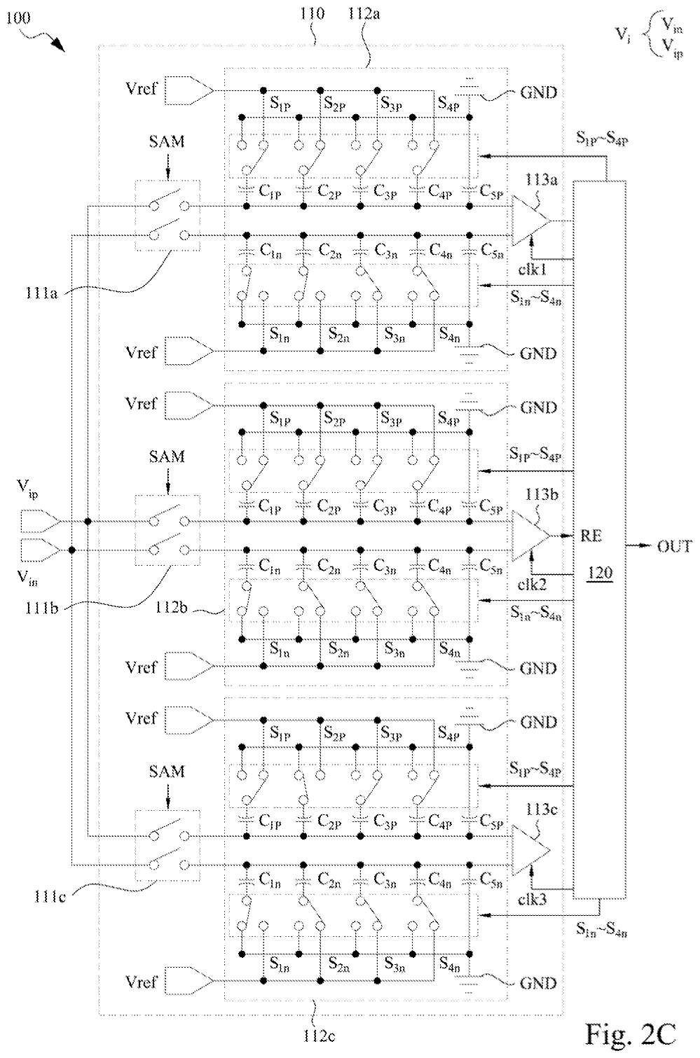

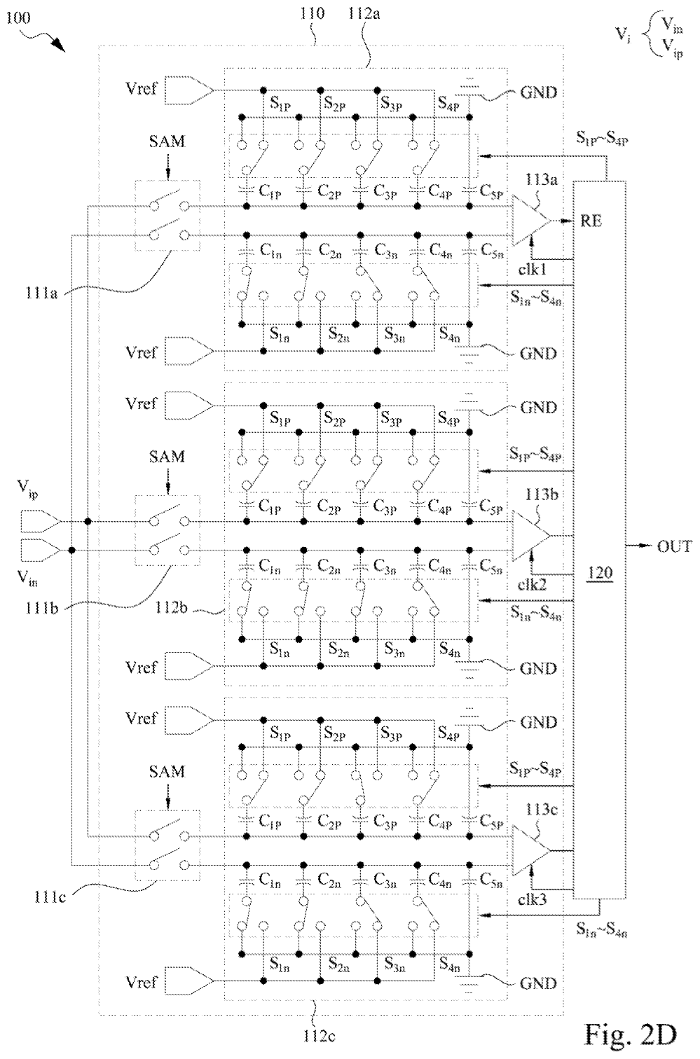

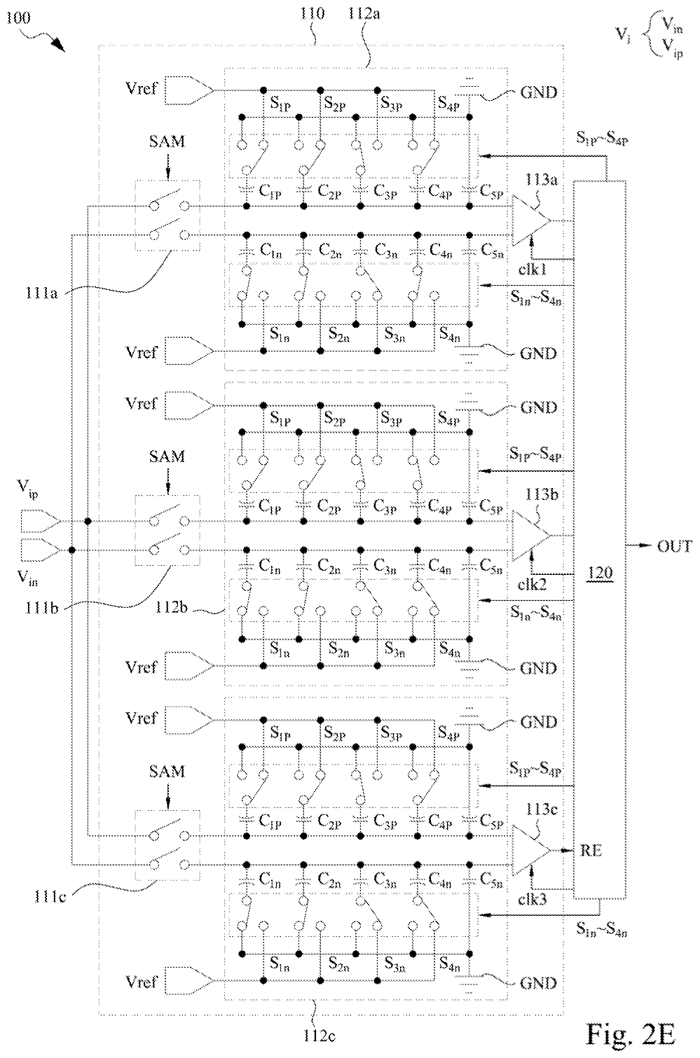

In some embodiments, the SAR ADC 100 operates in a top-plate sampling mode. The configurations and operations of the top plate sampling mode will be described in detail in following paragraphs and FIGS. 1, 2A-2E.

In some embodiments, the DAC array 110 is configured to receive the input signal Vi and comprises sampling switch circuits 111a, 111b, 111c, DACs 112a, 112b, 112c and comparators 113a, 113b, 113c. The sampling switch circuit 111a, DAC 112a and comparator 113a are connected in parallel to the sampling switch circuit 111b, DAC 112b and comparator 113b, and connected in parallel to the sampling switch circuit 111c, DAC 112c and comparator 113c.

The sampling switch circuit 111a is coupled between the input signal Vi and the DAC 112a, the sampling switch circuit 111b is coupled between the input signal Vi and the DAC 112b, and the sampling switch circuit 111c is coupled between the input signal Vi and the DAC 112c. In some embodiments, the sampling switch circuits 111a, 111b, and 111c are configured to receive a sampling signal SAM, and are turned on or turned off at the same time according to the sampling signal SAM, so as to make the DACs 112a, 112b, and 112c sample the input signal Vi.

The DAC 112a is coupled between the sampling switch circuit 111a and the comparator 113a, the DAC 112b is coupled between the sampling switch circuit 111b and the comparator 113b, and the DAC 112c is coupled between the sampling switch circuit 111c and the comparator 113c. In some embodiments, each of the DACs 112a, 112b and 112c comprises first capacitor switch circuits C1p-C5p. One terminal of each of the first capacitor switch circuits C1p-C5p is coupled to an input terminal of a corresponding comparator, and the other one terminal of each of the first capacitor switch circuits C1p-C5p is configured to receive the reference voltage Vref or a ground voltage GND, and the first capacitor switch circuits C1p-C5p are coupled in parallel with each other. For example, the first capacitor switch circuits C1p-C5p of the DAC 112a are coupled to the non-inverting input terminal of the comparator 113a, and the first capacitor switch circuits C1p-C5p of the DAC 112b are coupled to the non-inverting input terminal of the comparator 113b, and so on.

In some embodiments, the DACs 112a, 112b and 112c are configured to receive control signals S1p-S4p and control the first capacitor switch circuits C1p-C4p to receive the ground voltage GND or the reference voltage Vref according to the control signals S1p-S4p, thereby adjusting sampling results of the DACs 112a, 112b and 112c.

In some embodiments, each of the DACs 112a, 112b and 112c further comprises second capacitor switch circuits C1n-C5n. One terminal of each of the second capacitor switch circuits C1n-C5n is coupled to the other one input terminal of the corresponding comparator, and the other one terminal of each of the second capacitor switch circuits C1n-C5n is configured to receives the reference voltage Vref or the ground voltage GND, and the second capacitor switch circuits C1n-C5n are coupled in parallel with each other. For example, the second capacitor switch circuits C1n-C5n of the DAC 112a are coupled to the inverting input terminal of the comparator 113a, and the second capacitor switch circuits C1n-C5n of the DAC 112b are coupled to the inverting input terminal of the comparator 113b, and so on.

In this embodiment, the DACs 112a, 112b and 112c are further configured to receive control signals S1n-S4n and control the second capacitor switch circuits C1n-C4n to receive the ground voltage GND or the reference voltage Vref according to the control signals S1n-S4n, thereby adjusting the sampling results of the DACs 112a, 112b and 112c. In addition, the input signal Vi comprises sub-input signals Vip and Vin, and the sub-input signals Vip and Vin are differential signals. That is, the phases of the sub-input signals Vip and Vin are inverse to each other. The sub-input signal Vip is coupled to the first capacitor switch circuits C1p-C5p of each of the DACs 112a, 112b and 112c through the sampling switch circuits 111a, 111b and 111c. The sub-input signal Vin is coupled to the second capacitor switch circuits C1n-C5n of each of the DACs 112a, 112b and 112c through the sampling switch circuits 111a, 111b and 111c.

By using the first capacitor switch circuits C1p-C5p and the second capacitor switch circuits C1n-C5n, the SAR ADC 100 can sample and compare the differential input signal Vi. Therefore, compared with conventional SAR ADCs that only use a set of capacitor switch circuits and cannot sample differential signals, the SAR ADC 100 in FIG. 1 can obtain a more accurate conversion result OUT.

In some embodiments, the capacitance values of the first capacitor switch circuits C1p-C4p form a geometric sequence, and the capacitance values of the second capacitor switch circuits C1n-C4n also form a geometric sequence. The capacitance value of the first capacitor switch circuit C5p is equal to the capacitance value of the first capacitance switch circuit C4p, and the capacitance value of the second capacitance switch circuit C5n is equal to the capacitance value of the second capacitance switch circuit C4n. For example, the capacitance values of the first capacitor switch circuits C1p-C5p may be 8 Farad, 4 Farad, 2Farad, 1 Farad and 1 Farad respectively.

For example, when all of the first capacitor switch circuits C1p-C4p receive the ground voltage GND and all of the second capacitor switch circuits C1n-C4n receive the reference voltage Vref, the sampling result of the DAC will represent the conversion result OUT as a binary array “1111”; when all of the first capacitor switch circuits C1p-C4p receive the reference voltage Vref and all of the second capacitor switch circuits C1n-C4n receive the ground voltage GND, the sampling result of the DAC will represent the conversion result OUT as a binary array “0000”. In some embodiments, the larger the number in the array of conversion result OUT, the larger the voltage level corresponding to the sampling result of the DAC.

The comparator 113a is coupled between the DAC 112a and the SAR logic circuit 120, the comparator 113b is coupled between the DAC 112b and the SAR logic circuit 120, and the comparator 113c is coupled between the DAC 112c and the SAR logic circuits 120. The comparators 113a, 113b and 113c are configured to receive channel selection signals clk1-clk3 respectively from the

SAR logic circuit 120. Each of the channel selection signals clk1-clk3 is configured to enable one of the comparators 113a, 113b and 113c (e.g., the comparator 113a) to compare the sampling result of the corresponding DAC (e.g., the DAC 112a), and to disable (i.e., not perform comparison operations) the other two of the comparators 113a, 113b, and 113c, so as to make the enabled comparator (e.g., the comparator 113a) generate a comparison result RE.

The SAR logic circuit 120 is coupled to the DAC array 110 and configured to generate the control signals S1p-S4p and Sin-S4n according to the comparison result RE. The control signals S1p-S4p are sent to the switches that are coupled to each set of first capacitor switch circuits C1p-C4p, and the control signals S1n-S4n are sent to the switches that are coupled to each set of second capacitor switch circuits C1n-C4n , so as to adjust the sampling results of the DACs 112a, 112b and 112c. The SAR logic circuit 120 is further configured to generate the channel selection signals clk1-clk3 to determine the comparator to enable, and configured to generate the conversion result OUT according to the comparison result RE output by the enabled comparator.

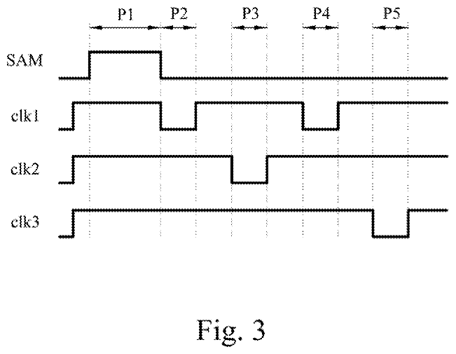

The operation method of the SAR ADC 100 is further described in FIGS. 2A-2E and FIG. 3. FIGS. 2A-2E are circuit diagrams of the SAR ADC 100 in time periods P1-P5 of FIG. 3 respectively in accordance with some embodiments of the present disclosure. FIG. 3 is a timing diagram of a sampling signal SAM and the channel selection signals clk1-clk3 in accordance with some embodiments of the present disclosure, and FIG. 3 comprises the time period P1 representing the sampling stage and the time periods P2-P5 representing different comparison stages.

First, please refer to FIG. 2A. During the time period P1 (shown in FIG. 3), the SAR ADC 100 enters the sampling stage and starts sampling the input signal Vi. At this time, the sampling signal SAM will be switched to an enabled level (i.e., logic high), and thus the sampling switch circuits 111a, 111b and 111c will be turned on. On the other hand, the channel selection signals clk1-clk3 will be at a disabled level (i.e., logic high), and thus the comparators 113a, 113b and 113c will not perform comparisons. In addition, the first capacitor switch circuits C1p-C4p and the second capacitor switch circuits C1n-C4n will be switched to receive the reference voltage Vref, to finish the initialization of the DACs 112a, 112b and 112c.

Next, please refer to FIG. 2B and FIG. 3. During the time period P2, the SAR ADC 100 enters a first comparison stage and starts comparing the input signal Vi.

Take the instance in FIG. 2B and FIG. 3 as an example, since the time period P2 is the first comparison stage, the SAR logic circuit 120 randomly chooses (or fixedly chooses) the comparator 113a to perform the comparisons, so as to change the channel selection signal clk1 to the enabled level.

In addition, the SAR logic circuit 120 adjusts the circuit structures of the DACs 112b and 112c corresponding to the unselected comparators 113b and 113c through the control signals S1p-S4p and S1n-S4n, so that the sampling results of the DACs 112b and 112c respectively correspond to the voltage levels corresponding to two cases that the first bit of the conversion result OUT (i.e., the most significant bit (MSB)) is 0 and 1. Please refer to FIG. 2B. The second capacitor switch circuit Cin of the DAC 112b is switched to receive the ground voltage GND, and thus the sampling result of the DAC 112b corresponds to the voltage level corresponding to the first bit of the conversion result OUT being 0; the first capacitor switch circuit C1p of the DAC 112c is switched to receive the ground voltage GND, and thus the sampling result of the DAC 112c corresponds to the voltage level corresponding to the first bit of the conversion result OUT being 1.

In the first comparison stage, the comparator 113a compares the sampling result of the DAC 112a with 0, to determine whether the sampling result of the DAC 112a is greater than 0 or less than 0. In this example, since the voltage level of the input signal Vi is less than 0, the SAR logic circuit 120 will record the first bit of the conversion result OUT as 0 according to the comparison result RE transmitted by the comparator 113a. Next, since the first bit of the conversion result OUT is recorded as 0, which corresponds to the sampling result of the DAC 112b (i.e., corresponds to the voltage level corresponding to the first bit of the conversion result OUT being 0), the SAR logic circuit 120 will choose the comparator 113b corresponding to the DAC 112b as the comparator for the next comparison, adjust the levels of the channel selection signals clk1-clk3, and then adjust the control signals S1p-S4p and S1n-S4n, so as to synchronously adjust the sampling results of the DACs 112a and 112c to the voltage level corresponding to the first bit of the conversion result OUT being 0, to finish the first comparison.

In other examples not shown, when the voltage level of the input signal Vi sampled by the DAC 112a (i.e., the sampling result of the DAC 112a) is greater than 0, the SAR logic circuit 120 will record the first bit of the conversion result

OUT as 1 according to the comparison result RE transmitted by the comparator 113a. Since the first bit of the recorded conversion result OUT is 1, which corresponds to the sampling result of the DAC 112c (i.e., corresponds to the voltage level corresponding to the first bit of the conversion result OUT being 1), the SAR logic The circuit 120 will choose the comparator 113c corresponding to the DAC 112c as the comparator for the next comparison, and synchronously adjust the sampling results of the DACs 112a and 112b to the voltage level corresponding to the first bit of the conversion result OUT being 1, to finish the first comparison.

Next, please refer to FIG. 2C and FIG. 3 together. During the time period P3,the SAR ADC 100 enters a second comparison stage and continues to compare the input signal Vi.

Take the instance in FIG. 2C and FIG. 3 as an example, since the SAR logic circuit 120 chooses the comparator 113b as the comparator for the next comparison at the end of the time period P2, the SAR logic circuit 120 will change the channel selection signal clk2 to the enabled level and change the channel selection signal clk1 to the disabled level.

In addition, the SAR logic circuit 120 adjusts the circuit structures of the DACs 112a and 112c corresponding to the unselected comparators 113a and 113c through the control signals S1p-S4p and S1n-S4n, so that the sampling results of the DACs 112a and 112c respectively correspond to the voltage levels corresponding to the two cases that the first two bits of the conversion result OUT are “00” and “01”. Please refer to FIG. 2C. The second capacitor switch circuit C2n of the DAC 112a is switched to receive the ground voltage GND, and thus the sampling result of the DAC 112a corresponds to the voltage level corresponding to the first two bits of the conversion result OUT being “00”; the first capacitor switch circuit C2p of the DAC 112c is switched to receive the ground voltage GND, and thus the sampling result of the DAC 112c corresponds to the voltage level corresponding to the first two bits of the conversion result OUT being “01”.

Next, the comparator 113b compares the sampling result of the DAC 112b with the voltage level corresponding to the first bit of the conversion result OUT being “0”. In this example, since the voltage level of the input signal Vi is lower than the voltage level corresponding to the first bit of the conversion result OUT being “0”, the SAR logic circuit 120 will record the second bit of the conversion result OUT as 0 according to the comparison result RE transmitted by the comparator 113b. Next, since the second bit of the conversion result OUT is recorded as 0, which corresponds to the sampling result of the DAC 112a (i.e., corresponds to the voltage level corresponding to the first two bits of the conversion result OUT being “00”), the SAR logic circuit 120 will choose the comparator 113a corresponding to the DAC 112a as the comparator for the next comparison, adjust the levels of the channel selection signals clk1-clk3, and then adjust the control signals S1p-S4p and S1n-S4n, so as to synchronously adjust the sampling results of the DACs 112b and 112c to the voltage level corresponding to the first two bits of the conversion result OUT being “00”, to finish the second comparison.

In other examples not shown, when the sampling result of the DAC 112b is greater than the voltage level corresponding to the first bit of the conversion result OUT being “0”, the SAR logic circuit 120 will record the second bit of the conversion result OUT as 1, and choose the comparator 113c corresponding to the DAC 112c as the comparator for next comparison, which will not be described here for the sake of brevity.

Next, please refer to FIG. 2D and FIG. 3 together. During the time period P4, the SAR ADC 100 enters a third comparison stage and continues to compare the input signal Vi.

Take the instance in FIG. 2D and FIG. 3 as an example, since the SAR logic circuit 120 chooses the comparator 113a as the comparator for the next comparison at the end of the time period P3, the SAR logic circuit 120 will change the channel selection signal clk1 to the enabled level and change the channel selection signal clk2 to the disabled level.

In addition, the SAR logic circuit 120 adjusts the circuit structures of the DACs 112b and 112c corresponding to the unselected comparators 113b and 113c through the control signals S1p-S4p and S1n-S4n, so that the sampling results of the DACs 112b and 112c respectively correspond to the voltage levels corresponding to the two cases that the first three bits of the conversion result OUT are “000” and “001”. Please refer to FIG. 2D. The second capacitor switch circuit C3n of the DAC 112b is switched to receive the ground voltage GND, and thus the sampling result of the DAC 112b corresponds to the voltage level corresponding to the first three bits of the conversion result OUT being “000”; the first capacitor switch circuit C3p of the DAC 112c is switched to receive the ground voltage GND, and thus the sampling result of the DAC 112c corresponds to the voltage level corresponding to the first three bits of the conversion result OUT being “001”.

Next, the comparator 113a compares the sampling result of the DAC 112a with the voltage level corresponding to the first two bits of the conversion result OUT being “00”. In this example, since the voltage level of the input signal Vi is greater than the voltage level corresponding to the first two bits of the conversion result OUT being “00”, the SAR logic circuit 120 will record the third bit of the conversion result OUT as 1 according to the comparison result RE transmitted by the comparator 113a. Next, since the third bit of the conversion result OUT is recorded as 1, which corresponds to the sampling result of the DAC 112c, the SAR logic circuit 120 will choose the comparator 113c corresponding to the DAC 112c as the comparator for the next comparison, adjust the levels of the channel selection signals clk1-clk3, and then adjust the control signals S1p-S4p and S1n-S4n, so as to synchronously adjust the sampling results of the DACs 112aand 112b to the voltage level corresponding to the first three bits of the conversion result OUT being “001”, to finish the third comparison.

In other examples not shown, when the sampling result of the DAC 112a is lower than the voltage level corresponding to the first two bits of the conversion result OUT being “00”, the SAR logic circuit 120 will record the third bit of the conversion result OUT as 0, and choose the comparator 113b corresponding to the DAC 112b as the comparator for next comparison, which will not be described here for the sake of brevity.

Next, please refer to FIG. 2E and FIG. 3 together. During the time period P5, the SAR ADC 100 enters a fourth comparison stage and continues to compare the input signal Vi.

Take the instance in FIG. 2E and FIG. 3 as an example, since the SAR logic circuit 120 chooses the comparator 113c as the comparator for the next comparison at the end of the time period P4, the SAR logic circuit 120 will change the channel selection signal clk3 to the enabled level and change the channel selection signal clk1 to the disabled level.

In addition, the SAR logic circuit 120 adjusts the circuit structures of the DACs 112a and 112b corresponding to the unselected comparators 113a and 113b through the control signals S1p-S4p and Sin-S4n, so that the sampling results of the DACs 112a and 112b respectively correspond to the voltage levels corresponding to the two cases that the four bits of the conversion result OUT are “0010” and “0011”. Please refer to FIG. 2E. The second capacitor switch circuit C4n of the DAC 112a is switched to receive the ground voltage GND, and thus the sampling result of the DAC 112a corresponds to the voltage level corresponding to the four bits of the conversion result OUT being “0010”; the first capacitor switch circuit C4p of the DAC 112b is switched to receive the ground voltage GND, and thus the sampling result of the DAC 112b corresponds to the voltage level corresponding to the four bits of the conversion result OUT being “0011”.

Next, the comparator 113c compares the sampling result of the DAC 112c with the voltage level corresponding to the first three bits of the conversion result OUT being “001”. In this example, since the voltage level of the input signal Vi is greater than the voltage level corresponding to the first three bits of the conversion result OUT being “001”, the SAR logic circuit 120 will record the fourth bit of the conversion result OUT as 1 according to the comparison result RE transmitted by the comparator 113c.

At last, the SAR ADC 100 can determine the four bits in the conversion result OUT to be “0011” based on the four comparison results RE generated in the four comparison stages, and then convert the analog input signal Vi into a digital conversion result OUT (i.e., an array).

In conclusion, in the n^{th} comparison stage (n is a positive integer), the SAR logic circuit 120 will choose a comparator based on the comparison result RE of the (n-1)^{th} comparison stage (in the first comparison stage, a certain comparator is randomly (or fixedly) selected), and change the channel selection signal sent to the selected comparator to the enabled level, so as to use this comparator for comparison. Next, the SAR logic circuit 120 will adjust the circuit structure of the DACs corresponding to the other two unselected comparators through the control signals S1p-S4p and S1n-S4n, so that the sampling results of the two DACs will respectively correspond to the voltage levels corresponding to the two cases that the n^{th} bit of the conversion result OUT is 0 and 1. At last, the selected comparator will compare the sampling result of its corresponding DAC with the voltage level corresponding to the first (n-1) bits of the conversion result OUT, and generate the corresponding comparison result RE, and the SAR logic circuit 120 will also use the control signal to synchronize the circuit structures of the three DACs based on the comparison result RE, and use the channel selection signal to adjust the comparator configured for comparison in the next comparison stage.

In addition, in each comparison stage, since the SAR logic circuit 120 has adjusted the sampling result of the unselected DAC to the voltage level corresponding to the two cases that the corresponding bit in the current comparison stage is 0 and 1 before the comparator performs comparison, the SAR DAC 100 can directly perform the next comparison by switching channels after finishing the comparison, thereby saving time waiting for the DAC to switch circuit structures.

It should be noted that the numbers of the first capacitor switch circuits and the second capacitor switch circuits in the DACs 112a, 112b and 112c in present disclosure is only an example, and is not intended to limit the present disclosure. Other numbers of the first capacitor switch circuits and the second capacitor switch circuits are within the scope of the present disclosure. In some embodiments, each of the DACs 112a, 112b, and 112c comprises less than five first capacitor switch circuits and second capacitor switch circuits to achieve faster conversion speeds. In some embodiments, each of the DACs 112a, 112b, and 112c comprises more than five first capacitor switch circuits and second capacitor switch circuits to achieve higher resolution.

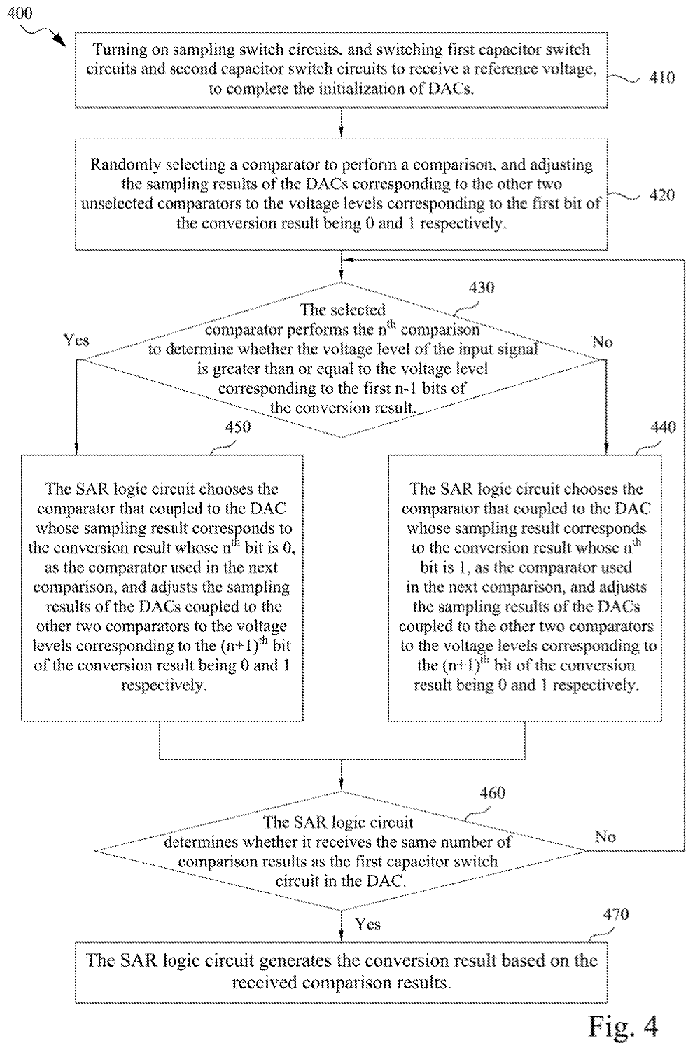

FIG. 4 is a flowchart of an operation method 400 for operating the SAR ADC 100 in accordance with some embodiments of the present disclosure. In some embodiments, the operation method 400 comprises steps 410, 420, 430, 440, 450, 460 and 470.

In step 410, the SAR ADC 100 enters the sampling stage, the sampling signal SAM is switched to the enabled level to turn on the sampling switch circuits 111a, 111b and 111c, and the first capacitor switch circuits C1p-C4p and the second capacitor switch circuit Cin-C4n are switched to receive the reference voltage Vref, so as to complete an initialization of the DACs 112a, 112b and 112c.

In step 420, the SAR logic circuit 120 randomly chooses a comparator to perform a comparison, and adjusts the sampling results of the DACs corresponding to the other two unselected comparators to the voltage levels corresponding to the first bit of the conversion result OUT being 0 and 1.

In step 430, the selected comparator performs the n^{th} comparison to compare the voltage level of the input signal Vi and the voltage level corresponding to the first (n-1) bits of the conversion result OUT, wherein n is a positive integer. When the voltage level of the input signal Vi is greater than or equal to the voltage level corresponding to the first (n-1) bits of the conversion result OUT, step 440 is performed; when the voltage level of the input signal Vi is lower than the voltage level corresponding to the first (n-1) bits of the conversion result OUT, step 450 is performed.

In step 440, the selected comparator generates the comparison result RE to the SAR logic circuit 120. The SAR logic circuit 120 chooses the comparator corresponding to the sampling result of the DAC corresponding to the n^{th} bit of the conversion result OUT being 1 as the comparator used in the next comparison (i.e., the (n+1)^{th} comparison), and adjusts the sampling results of the DACs corresponding to the other two comparators to the voltage levels corresponding to the (n+1)^{th} bit of the conversion result OUT being 0 and 1 respectively.

In step 450, the selected comparator generates the comparison result RE to the SAR logic circuit 120. The SAR logic circuit 120 chooses the comparator corresponding to the sampling result of the DAC corresponding to the n^{th} bit of the conversion result OUT being 0 as the comparator used in the next comparison (i.e., the (n+1)^{th} comparison), and adjusts the sampling results of the DACs corresponding to the other two comparators to the voltage levels corresponding to the (n+1)^{th} bit of the conversion result OUT being 0 and 1 respectively.

In step 460, the SAR logic circuit 120 determines whether it receives the same number of comparison results RE as the first capacitor switch circuit in the DAC (i.e., the judgment of all bits of the conversion result OUT is completed). When the DAC array 110 has received the same number of comparison results RE as the first capacitor switch circuits in the DAC, step 470 is performed; when the DAC array 110 has not received the same number of comparison results RE as the first capacitor switch circuits in the DAC, step 430 is performed repeatedly.

In step 470, the SAR logic circuit 120 generates a conversion result OUT according to the plurality of received comparison results RE.

It should be noted that the number and order of steps in the operation method 400 in present disclosure are only examples, and are not intended to limit the present disclosure. The other number and order of steps are within the scope of the present disclosure. In some embodiments, step 460 may be omitted.

With the SAR ADC 100 and the operation method 400 of the same in the present disclosure, comparisons can be performed in turn by using a plurality of DACs and comparators inside the SAR ADC 100 to save time waiting for the internal circuit structure of the DAC to switch, thereby improving the efficiency of the SAR ADC 100 in converting analog signals into digital signals while maintaining its resolution.

The above are preferred embodiments of the present disclosure. It will be apparent to those skilled in the art that various modifications and variations can be made to the structure of the present disclosure without departing from the scope or spirit of the present disclosure. In view of the foregoing, it is intended that the present disclosure cover modifications and variations of this disclosure provided they fall within the scope of the following claims and their equivalents.

What is claimed is:

1. A successive approximation register (SAR) analog-to-digital converter (ADC), configured to receive an input signal and comprising:
a digital-to-analog converter (DAC) array, configured to receive the input signal and comprising:
three DACs, configured to sample an input voltage level of the input signal; and
three comparators, respectively connected in series with the three DACs, and configured to respectively generate a comparison result; and
a SAR logic circuit, coupled to the DAC array, and configured to generate the n^{th} bit of a conversion result according to the comparison result in an n^{th} comparison stage,
wherein in the n^{th} comparison stage, the SAR logic circuit is configured to:
choose a first comparator of the three comparators to compare a sampling result of a first DAC of the three DACs with the voltage level corresponding to the first (n-1) bits of the conversion result, according to the comparison result of an (n-1)^{th} comparison stage, to generate the comparison result, and
adjust sampling results of a second DAC and a third DAC of the three DACs corresponding to a second comparator and a third comparator of the three comparators to the voltage levels respectively corresponding to the cases where the n^{th} bit of the conversion result is 0 and 1, and wherein n is a positive integer greater than 1.

2. The SAR ADC of claim 1, wherein the DAC array further comprises three sampling switch circuits respectively coupled between the input signal and the three DACs,
wherein the three DACs are configured to be turned on in a sampling stage according to a sampling signal to make the DAC array sample the input signal, and configured to be turned off according to the sampling signal in the plurality of comparison stages.

3. The SAR ADC of claim 1, wherein each of the three DACs comprises a plurality of first capacitor switch circuits,
wherein the plurality of first capacitor switch circuits of each of the three DACs are coupled to each other in parallel and coupled to an input terminal of a corresponding one of the three comparators, and are configured to be respectively coupled to a reference voltage or a ground voltage according to a plurality of control signals.

4. The SAR ADC of claim 3, wherein the capacitance values of the plurality of first capacitor switch circuits of each of the three DACs form a geometric sequence.

5. The SAR ADC of claim 3, wherein each of the three DACs further comprises a plurality of second capacitor switch circuits,
wherein the number of the plurality of second capacitor switch circuits is equal to the number of the plurality of first capacitor switch circuits,
wherein the plurality of second capacitor switch circuits of each of the three DACs are coupled to each other in parallel and coupled to an another input terminal of the corresponding one of the three comparators, and are configured to be respectively coupled to the reference voltage or the ground voltage according to the plurality of control signals.

6. The SAR ADC of claim 3, wherein the number of the plurality of comparison stages is equal to the number of the plurality of first capacitor switch circuits of each of the three DACs, and is equal to the number of the plurality of comparison results.

7. The SAR ADC of claim 1, wherein when the input signal is greater than or equal to the voltage level corresponding to the first (n-1) bits of the conversion result, the SAR logic circuit chooses the third comparator corresponding to the third DAC to perform a comparison in a (n+1)^{th} comparison stage, and synchronously adjusts the two sampling results of the first DAC and the second DAC to the voltage level corresponding to the case where the n^{th} bit of the conversion result is 1.

8. The SAR ADC of claim 7, wherein when the input signal is lower than the voltage level corresponding to the first (n-1) bits of the conversion result, the SAR logic circuit chooses the second comparator corresponding to the second DAC to perform a comparison in a (n+1)^{th} comparison stage, and synchronously adjusts the two sampling results of the first DAC and the third DAC to the voltage level corresponding to the case where the n^{th} bit of the conversion result is 0.

9. The SAR ADC of claim 1, wherein in a first comparison stage, the SAR logic circuit is configured to choose a random one of the three comparators for performing a comparison.

10. The SAR ADC of claim 1, wherein the conversion result is an array comprising a plurality of bits, and each of the plurality of comparison results respectively corresponds to each of the plurality of bits.

11. An operation method for operating a SAR ADC, wherein the SAR ADC is configured to receive an input signal and comprises a DAC array and a SAR logic circuit, and the operation method comprises:
(a) in an n^{th} comparison stage, choosing a first comparator of three comparators of the DAC array by the SAR logic circuit, to compare a sampling result of a first DAC of three DACs of the DAC array with the voltage level corresponding to the first (n-1) bits of a conversion result, according to the comparison result of an (n-1)^{th} comparison stage, to generate a comparison result, and
adjusting sampling results of a second DAC and a third DAC of the three DACs corresponding to a second comparator and a third comparator of the three comparators to the voltage levels respectively corresponding to the cases where the n^{th} bit of the conversion result is 0 and 1 by the SAR logic circuit;
(b) comparing the input signal with the voltage level corresponding to the first (n-1) bits of the conversion result by the first comparator, to generate the comparison result;
(c) generating the n^{th} bit of the conversion result according to the comparison result by the SAR logic circuit; and
(d) repeating steps (a)-(c),
wherein the DAC array is coupled between the input signal and the SAR logic circuit, and the three comparators are respectively connected in series with the three DACs,
wherein n is a positive integer greater than 1.

12. The operation method of claim 11, further comprising:
(e) in a sampling stage, turning on three sampling switch circuits of the DAC array by a sampling signal, to make the DAC array sample the input signal, and
in the plurality of comparison stages, turning off the three sampling switch circuits by the sampling signal,
wherein the three sampling switch circuits are respectively coupled between the input signal and the three DACs.

13. The operation method of claim 11, wherein step (a) further comprises:
respectively coupling a plurality of first capacitor switch circuits of the three DACs to a reference voltage or a ground voltage by a plurality of control signals,
wherein the plurality of first capacitor switch circuits of each of the three DACs are coupled to each other in parallel and coupled to an input terminal of a corresponding one of the three comparators.

14. The operation method of claim 13, wherein the capacitance values of the plurality of first capacitor switch circuits of each of the three DACs form a geometric sequence.

15. The operation method of claim 13, wherein step (a) further comprises:
respectively coupling a plurality of second capacitor switch circuits of the three DACs to the reference voltage or the ground voltage by the plurality of control signals,
wherein the number of the plurality of second capacitor switch circuits is equal to the number of the plurality of first capacitor switch circuits,
wherein the plurality of second capacitor switch circuits of each of the three DACs are coupled to each other in parallel and coupled to an another input terminal of the corresponding one of the three comparators.

16. The operation method of claim 13, wherein the number of the plurality of comparison stages is equal to the number of the plurality of first capacitor switch circuits of each of the three DACs, and is equal to the number of the plurality of comparison results.

17. The operation method of claim 11, wherein step (b) further comprises:
when the input signal is greater than or equal to the voltage level corresponding to the first (n-1) bits of the conversion result, choosing the third comparator corresponding to the third DAC to perform a comparison in a (n+1)^{th}comparison stage, and synchronously adjusting the two sampling results of the first DAC and the second DAC to the voltage level corresponding to the case where the n^{th} bit of the conversion result is 1, by the SAR logic circuit.

18. The operation method of claim 17, wherein step (b) further comprises:
when the input signal is lower than the voltage level corresponding to the first (n-1) bits of the conversion result, choosing the second comparator corresponding to the second DAC to perform a comparison in a (n+1)^{th} comparison stage, and synchronously adjusting the two sampling results of the first DAC and the third DAC to the voltage level corresponding to the case where the n^{th} bit of the conversion result is 0, by the SAR logic circuit.

19. The operation method of claim 11, wherein step (a) further comprises:
in a first comparison stage, choosing a random one of the three comparators for performing a comparison, by the SAR logic circuit.

20. The operation method of claim 11, wherein step (c) comprises:
generating the conversion result comprising an array with a plurality of bits according to the conversion result by the SAR logic circuit,
wherein each of the plurality of comparison results respectively corresponds to each of the plurality of bits.
